(19) United States
(12) Patent Application Publication
(10) Pub. No.: US 2023/0296955 A1
(43) Pub. Date: Sep. 21, 2023

(54) ELECTRO-OPTICAL APPARATUS, SEMICONDUCTOR APPARATUS AND SEMICONDUCTOR DEVICE, ELECTRO-OPTICAL ARRANGEMENT AND USE

(71) Applicant: Gesellschaft für Angewandte Mikro- und Optoelektronik mit beschränkter Haftung - AMO GmbH, Aachen (DE)

(72) Inventors: Daniel SCHALL, Aachen (DE); Stephan SUCKOW, Aachen (DE)

(21) Appl. No.: 18/018,341

(22) PCT Filed: Jul. 28, 2021
(86) PCT No.: PCT/EP2021/071123

§ 371 Date: Jan. 27, 2023

(30) Foreign Application Priority Data
Jul. 28, 2020 (DE) 20 2020 104 362.5

(51) Int. Cl. G02F 1/225; G02F 1/21; H01L 31/02

(52) U.S. Cl. CPC G02F 1/225; G02F 1/212; H01L 31/02005

(57) ABSTRACT

The present invention relates to an electro-optical device (1) having two interaction regions (2), which each comprise a longitudinal waveguide section (3) and one or two active elements (5), which active element or the respective active element comprises or consists of at least one electro-optical active material, more particularly graphene, wherein the longitudinal waveguide sections (3) of the two interaction regions (2) are arranged spaced apart from one another, and the active element or the respective active element (5) extends at least in some sections above and/or below and/or within the waveguide longitudinal section (3) of the respective interaction region (2), and wherein two or more contact elements (6) are provided which are each in contact with at least one of the active elements (5).

The invention relates to an electro-optical device, in particular a photodetector or a modulator. Furthermore, the invention relates to a semiconductor apparatus having a chip and at least one electro-optical device, a semiconductor device having a wafer and at least one electro-optical device, an electro-optical arrangement and a use.

Electro-optical devices, for example photodetectors or electro-optical modulators, are known from the prior art. These comprise, for example, a waveguide or a longitudinal section of such a waveguide and—in the case of a photodetector—one or—in the case of an electro-optical modulator—two films of graphene as active elements. Such devices are disclosed, for example, in U.S. Pat. No. 9,893,219 B2. The active element(s) overlaps the longitudinal waveguide section. One can also speak of waveguide-integrated photodetectors or modulators. The active element(s) is/are in contact with contact elements arranged on the side of the waveguide, via which a connection to further components is achieved. The contact elements can be provided, for example, by films or coats of metal, via which an electrical coupling of the active element(s) with further components is possible. In operation, an interaction between electromagnetic radiation guided by the waveguide and the graphene film(s) can take place. The region, in which the graphene film(s) overlaps the waveguide, can also be understood and referred to as the interaction region.

From the paper “CMOS-compatible graphene photodetektor covering all optical communication bands” from A. Pospischil et al., Nature Photonics, 15 (2013), pages 892 to 896, another graphene photodetector with a longitudinal waveguide section and an active element given by a graphene film, which overlaps the section of the waveguide and is in contact with two contact elements arranged laterally of the waveguide, is known. According to this publication, a third contact element is provided on the graphene film above the waveguide in addition to the two contact elements arranged laterally. The three contact elements serve as ground and signal contacts, specifically as a center signal contact and two lateral ground contacts. In other words, a ground-signal-ground-configuration (abbreviated G-S-G or gnd-s-gnd configuration) can thus be achieved, which has advantages. The main advantage of the arrangement is the symmetrical generation of a high-frequency signal, which allows good coupling to external devices via coplanar and coaxial conductors. The pre-known photodetector with a G-S-G-configuration has proven itself. However, it is sometimes considered as disadvantageous that a metallic contact element arranged above the waveguide can lead to light absorption and thus to a decrease in the performance of the device.

Based on this, it is an object of the present invention to provide an alternatively designed electro-optical device, which offers the advantage of a G-S-G configuration and at the same time avoids or at least reduces the disadvantages of the prior art.

According to a first aspect of the invention, this object is solved by an electro-optical device, in particular a photodetector or a modulator, having two interaction regions, which each comprise a longitudinal waveguide section and one or two active elements, the active element or elements each comprising or consisting of at least one electro-optically active material, in particular graphene, the longitudinal waveguide sections of the two interaction regions being arranged spaced apart from one another and the respective active element or elements extending at least in sections above and/or below and/or within the longitudinal waveguide section of the respective interaction region, and two or more contact elements being provided, which contact elements are each in contact with at least one of the active elements, wherein at least one inner contact element, which is arranged between the two spaced-apart longitudinal waveguide sections and serves an inner signal contact, and two outer contact elements, which are each arranged on the other side of the respective longitudinal waveguide section with respect to the inner contact element and each serve as an outer ground contact, or one outer contact element, which is formed at least in sections at least substantially in a U-shape with two arms spaced apart from one another and a connecting section connecting the two arms and which engages around the outside of the two longitudinal waveguide sections, the two arms of the outer contact element each serving at least in sections as an outer ground contact, are provided.

In other words, the invention is based on the idea of providing two interaction regions, each having a longitudinal waveguide section, in an electro-optical device, in particular photodetector or a modulator. The longitudinal waveguide sections are spaced apart from one another so that space is available between them to provide an additional contact element there, which is not associated with the disadvantage of a contact element arranged on a waveguide. As a result, a G-S-G configuration with a central signal contact and two lateral ground contacts can be achieved without the disadvantage of undesired interactions between signal contact and waveguide. In particular for the connection of high-frequency components to coplanar or coaxial interfaces, arrangements with a central signal contact and lateral ground contacts, in particular symmetrical components with respect to ground and signal, are advantageous, since the high-frequency signals can be transmitted more interference-free to coplanar or coaxial arrangements. This in particular applies if an electro-optical device, such as a photodetector or a modulator, is arranged on a planar chip surface or forms part of such a surface, then a particularly interference-free transmission from the planar chip surface to coplanar or coaxial arrangements can be achieved.

In the case that an inner contact element, preferably exactly one inner contact element is provided, this inner contact element is preferably in contact both with the active element or one of the active elements of one interaction region and with the active element or one of the active elements of the other interaction region. In other words, there is a common inner contact element between the longitudinal waveguide sections, which is assigned to both interaction regions and, in particular, forms a common electrical (signal) connection to the active element or one of the active elements of both interaction regions.

If two inner contact elements are provided, it is preferred that one of the inner contact elements is in contact with the active element or one active element of one interaction region and the other inner contact element is in contact with the active element or one active element of the other interaction region. The two inner contact elements may be electrically connected to each other and/or to a common (signal) connection point.

Furthermore, if one, preferably exactly one, outer contact element is provided, it may be in contact both with the active element or one of the active elements of one interaction region and with the active element or one of the active elements of the other interaction region.

If two outer contact elements are present, it is preferred, that one of the outer contact elements is in contact with the active element or one active element of one interaction region and the other outer contact element is in contact with the active element or one active element of the other interaction region.

It has proven to be particularly advantageous if there are exactly one inner contact element connected to the active element or an active element of both interaction regions and exactly two outer contact elements, each of which is only in contact with the active element or one active element of one of the two interaction regions.

The outer contact elements are then preferably arranged on two opposite sides of the inner contact element. The outer contact element(s) and the inner contact element(s) are particularly preferably arranged on a line.

With regard to the two longitudinal waveguide sections, it applies in a further advantageous embodiment that they are part of one waveguide. In other words, there are two spaced-apart sections of one waveguide then.

A particularly suitable example of such an embodiment is given by a waveguide comprising a bifurcation with two branching arms, wherein each of the longitudinal waveguide sections is located in the region of each arm of the bifurcation respectively.

A splitter is preferably provided then, by means of which an incoming light signal can be distributed to the two arms of the bifurcation, preferably in equal proportions. Space is available between the two arms of the bifurcation for the at least one inner contact element then and a G-S-G configuration can be obtained in a particularly suitable manner.

It should be noted that, in the present context, light is not only to be understood as electromagnetic radiation of the spectral range visible to the human eye, but also as electromagnetic radiation outside this range, for example of the infrared and/or ultraviolet wavelength range.

Particularly preferably, the splitter is designed as a 50/50 splitter, by means of which two equally large output signals can be obtained from one input signal. The splitter can, for example, be designed as an MMI-splitter or a directional coupler or comprise such a coupler. MMI stands for Multi Mode Interference.

The embodiment with bifurcation can—in particular in the case of a detector—offer the advantage of symmetrical absorption.

In a further particularly advantageous embodiment, the waveguide is characterized, at least in sections, by a substantially U-shaped course with two arms being spaced apart from one another, preferably extending at least substantially parallel to one another and in particular being rectilinear, and a preferably rectilinear connecting section connecting the two arms, wherein one of the two longitudinal waveguide sections lies in the region of one of the two arms respectively. Then space is available within the U-shaped section for the at least one inner contact element and a G-S-G configuration can be obtained in a particularly suitable manner.

According to a second aspect of the invention, the above mentioned object is further solved by an electro-optical device, in particular a photodetector or a modulator, having an interaction region, which has an at least substantially U-shaped longitudinal waveguide section, which longitudinal waveguide section has two arms spaced apart from one another and a connecting section connecting the two arms, and one or two at least sectionally at least substantially U-shaped active elements having two arms spaced apart from one another and a connecting section connecting the two arms, wherein the active element or the respective active element comprises or consists of at least one electro-optically active material, in particular graphene, wherein the active element or the respective active element extends at least in sections above and/or within the longitudinal waveguide section and wherein two or more contact elements are provided, which are each in contact with the active element or one of the active elements, wherein at least one inner contact element, which is arranged within the at least sectionally at least substantially U-shaped longitudinal waveguide section and serves as an inner signal contact, and two outer contact elements, which are each arranged on the other side of the respective arm of the longitudinal waveguide section with respect to the inner contact element and each serve as an outer ground contact, or one outer contact element, which is formed at least in sections at least substantially U-shaped and has two arms spaced apart from one another and a connecting section connecting the two arms and which encompasses the outside of the longitudinal waveguide section, the two arms of the outer contact element each serving at least in sections as an outer ground contact, are provided.

In other words, instead of two separate spaced-apart interaction regions with spaced-apart longitudinal waveguide sections and separate active elements, there may also be a continuous interaction region of an at least substantially U-shaped configuration, in which space is available for the at least one inner contact element. In the second aspect, the respective active element(s) is/are also substantially U-shaped and the active element(s) expediently extend(s) not only in the region of the arms of the longitudinal waveguide section above and/or within the latter, but also in the region of the connecting section connecting the arms.

The at least substantially U-shaped longitudinal waveguide section is in a further development part of a non-annularly closed waveguide. In particular, it is part of an open waveguide. In this context, an annularly waveguide is to be understood as one which, due to the annular arrangement, has neither a beginning nor an end, so that coupled-in light propagates in this resonator and interferes with itself. This is not the case with an open waveguide, where light propagates along the course of the waveguide and is not returned to itself, so that it does not interfere with itself.

In another especially preferred embodiment, the cross-sectional area in the region of one arm of the waveguide is larger than the cross-sectional area in the region of the other arm of the waveguide. The cross-sectional area is then expediently larger in the first arm as viewed the light propagation direction than in the second arm as viewed in the light propagation direction.

While a U-shaped waveguide section is very suitable for providing space for at least one inner signal contact, there may be a disadvantage associated with it in terms of symmetry of the electrical signal. According to Lambert-Beer's law, the absorption of electromagnetic radiation along the propagation direction leads to more absorption in the active element(s) in the region of the first arm than in the one(s) of the second. Then the high-frequency mode can be symmetrically excited in an unfavourable way. To circumvent this problem, the waveguide cross-section in the U-shaped region of the waveguide can be specifically adapted so that the interaction of the light per length along the propagation direction with the active element(s) in the first arm is just so much less compared to the second arm that the absorbed power in both arms becomes or is just identical. For this purpose, for example, the waveguide cross-section in the first arm can be widened in order to guide the optical mode further inside the waveguide and thus reduce the interaction in the first arm. The aim of the adjustment is to absorb half the power in the first arm compared to the power available at the beginning.

Also in the second aspect, if at least one, preferably exactly one inner contact element is provided, this may be in contact both with the one arm of the active element or of one of the active elements and with the other arm of the active element or of one of the active elements.

Alternatively, it is of course also possible, that, if two inner contact elements are provided, one of the two inner contact elements is in contact with one arm of the active element or of one of the active elements and the other inner contact element is in contact with the other arm of the active element or of one of the active elements.

Furthermore, in case that one, in particular exactly one outer contact element is provided, this may be in contact both with the one arm of the active element or of one of the active elements and with the other arm of the active element or of one of the active elements.

If two outer contact elements are provided, it preferably applies that one of the outer contact elements is in contact with the one arm of the active element or of one of the active elements and the other contact element is in contact with the other arm of the active element or of one of the active elements.

Both for the inventive electro-optical device according to the first aspect and for the inventive electro-optical device according to the second aspect, if it is designed as a preferably electro-optical modulator, it applies that the respective interaction region or regions can comprise two active elements. Then, preferably, the inner contact element or one of the inner contact elements is in contact with the active element of the interaction region or of the respective interaction region and the outer contact element or one of the outer contact elements is in contact with the other active element of the interaction region or of the respective interaction region. In particular, the respective contact element can be in contact with the respective element on one lateral side thereof.

Alternatively to two active elements, it may also be provided, that the interaction region or the respective interaction region comprises an active element and an electrode, preferably, wherein the inner contact element or one of the inner contact elements is in contact with the active element of the interaction region or of the respective interaction region and the outer contact element or one of the outer contact element is in contact with the electrode of the interaction region or of the respective interaction region, or vice versa.

The respective contact element can in particular be in contact with the respective active element or the respective electrode on one lateral side thereof.

Vice versa means that the respective electrode is in contact with the inner contact element and the respective active element is in contact with the outer contact element.

If instead of two active elements there is one active element and one electrode, in a further development it can also apply to the electrode that it is at least in sections at least substantially U-shaped with two arms and a connecting section connecting the arms. The arms can be rectilinear and extend parallel to each other. The connecting section may also be rectilinear.

Expediently, the two active elements or the active element and the electrode of the interaction region or of the respective interaction region are then spaced apart from one another and are arranged offset with respect to one another in such a way that they lie one above the other in sections in an overlap region.

In other words, a section of one active element then aligns or overlaps with a section of the other active element or the electrode, expediently without them touching. Preferably, at least in the overlap region, the two active elements or the respective two active elements or the active element or the respective active element and the electrode or the respective electrode or at least sections thereof extend at least substantially parallel to one another.

In a further particularly advantageous embodiment, the extent of the overlap region in the transverse direction is in the range from 10 nm to 1000 nm. Preferably, it corresponds to the width of the waveguide.

In case, the longitudinal waveguide section or one of the longitudinal waveguide sections has at least one gap, it preferably applies, that the overlap region is arranged above or below the gap or at least one of the gaps.

If an element or section is at least substantially U-shaped with two arms and a connecting section, the arms may further extend at least substantially parallel to each other and/or be rectilinear. The connecting section may also be rectilinear.

In further embodiment of both the first aspect and the second aspect, a waveguide bypass section may be provided, the waveguide bypass section bridging the one interaction region or the two interaction regions, so that light originating in particular from the same source can be guided past the one interaction region or past the two interaction regions through the waveguide bypass section. It is then further preferred that the device is formed as an interferometer or as a component of an interferometer. Alternatively or additionally, a splitter can be provided by means of which light can be split on the one hand to the waveguide bypass section and on the other hand to the longitudinal waveguide section of the interaction region or to the longitudinal waveguide sections of the interaction regions.

In a further development, the same as described above for the variant with the bifurcation can apply to the splitter.

The longitudinal waveguide section of the interaction region or the longitudinal waveguide sections of the interaction regions may further be part of a waveguide, at one end of which a coupling device for coupling light in and/or out is provided, or at both ends of which a coupling device for coupling light in and/or out is provided respectively.

In the case of a modulator, in which two active elements are assigned to each of the longitudinal waveguide sections, it is further preferred that the or each of the two active elements are spaced apart from one another and are arranged offset from one another in such a way that they lie in sections one above the other in an overlap region. If, in the case of a modulator, an active element and a (conventional) electrode are assigned to each of the longitudinal waveguide sections, it can in a preferred embodiment analogously apply that the active element or the respective active element and the electrode or the respective electrode are spaced apart from one another and are arranged offset from one another in such a way that they lie in sections one above the other in an overlap region. In other words, a section of one active element then aligns or overlaps with a section of the other active element or of the electrode, expediently without them touching. Preferably, at least in the overlap region, the active element or each active element and the electrode or each electrode or at least sections thereof extend at least substantially parallel to each other.

In case the longitudinal waveguide sections or one of the longitudinal waveguide sections has/have at least one gap, it is preferably the case that the overlap region is arranged above or below the gap or at least one of the gaps and preferably corresponds to the gap width.

A longitudinal waveguide section is in particular to be understood as a section of a waveguide which extends only over a part of the total extent of a waveguide in its longitudinal direction, preferably coinciding with the light propagation direction, and over the entire cross-section of the waveguide.

An electro-optical device according to the invention can be designed, for example, as a photodetector or an in particular electro-optical modulator. It can also be in the form of an interferometer, for example a Mach-Zehnder interferometer, or form a component or a part of an interferometer, for example of a Mach-Zehnder interferometer. For example, an electro-optical device according to the invention configured as a modulator may be a component of a Mach-Zehnder-based phase modulator arrangement.

It should be noted that a photodetector may in particular serve for signal conversion back from the optical to the electronic world. An electro-optical modulator may in particular be used for optical signal coding. An electro-optical modulator may also be embodied as a ring modulator.

The active element or elements of the electro-optical device according to the invention comprise(s) at least one electro-optically active material or consist of one or more of such materials.

One can speak of an electro-optically active material in particular if the material absorbs electromagnetic radiation of at least one wavelength and generates an electrical photosignal as a result of the absorption, and/or its refractive index changes as a function of a voltage and/or the presence of charge and/or an electric field.

That a material changes its refractive index is to be understood in particular such that it changes its dispersion (in particular refractivity) and/or its absorption. The dispersion or refractivity is usually given by the real part and the absorption by the imaginary part of the complex refractive index. Materials whose refractive index changes as a function of a voltage and/or the presence of charge(s) and/or an electric field are understood herein to be, in particular, those characterized by the Pockels effect and/or the Franz-Keldysh effect and/or the Kerr effect. In addition, materials that are characterized by the plasma dispersion effect are also considered to be such materials.

It has been proven to be particularly suitable if the at least one electro-optically active material of at least one of the active elements is graphene, possibly chemically modified graphene, and/or at least one dichalcogenide, in particular two-dimensional transition metal dichalcogenide, and/or heterostructures of two-dimensional materials and/or germanium.

Many materials are characterized both by the fact that their refractive index changes as a function of a voltage and/or the presence of charge and/or an electric field, and by the fact that they absorb electromagnetic radiation of at least one wavelength and generate an electrical photosignal as a result of the absorption. For graphene, for example, this is the case. Graphene is accordingly suitable for both the active elements of photodetectors and modulators. This also applies to dichalcogenides, such as two-dimensional transition metal dichalcogenides, heterostructures of two-dimensional materials, germanium, silicon, as well as compound semiconductors, in particular III-V semiconductors and/or II-VI semiconductors. Lithium niobate, for example, is generally only suitable for modulators. Since it is transparent, it does not fulfill the absorbing property and is therefore not suitable for photodetectors.

It may be that the at least one electro-optically active material of at least one of the active elements is one that can absorb electromagnetic radiation of a wavelength of 850 nm and/or 1310 nm and/or 1550 nm and generate a photosignal as a result of the absorption. It is particularly preferred that it absorbs electromagnetic radiation in the wavelength range from 800 nm to 900 nm and/or from 1260 nm to 1360 nm (so-called original band or O-band for short) and/or from 1360 nm to 1460 nm (so-called extended band or E-band for short) and/or from 1460 nm to 1530 nm (so-called short band or S-band for short) and/or from 1530 nm to 1565 nm (so-called conventional band or C-band for short) and/or from 1565 nm to 1625 nm (so-called long band or L-band for short) and can generate a photosignal as a result of the absorption.

Alternatively or additionally, it may be provided that the active element or at least one of the active elements assigned to the longitudinal waveguide section and/or the further longitudinal waveguide section is in the form of a film. A film is preferably characterized in a manner known per se by a significantly greater lateral extent than thickness. The active element or at least one of the active elements may further be characterized by a square or rectangular cross-section.

The active element or at least one active element may also comprise one or more layers or coats of at least one material whose refractive index changes and/or which absorbs, or may be formed from one or more layers or coats of at least one such material. It may also be provided that the active element or at least one active element is formed as a film comprising several layers or coats of one or also different materials.

Films of graphene, possibly chemically modified graphene, or also dichalcogenide-graphene heterostructures consisting of at least one layer of graphene and at least one layer of a dichalcogenide or arrangements of at least one layer of boron nitride and at least one layer of graphene have proven to be particularly suitable.

It may also be provided that at least one of the active elements comprises or consists of one or more silicon coats.

The active element or the active elements may further be doped or comprise doped portions or regions, for example be p-doped and/or n-doped or comprise corresponding sections or regions. It may also be that a p-doped region and an n-doped region and a preferably intermediate undoped region are present or provided. This is also referred to as a pin-junction, where the i stands for intrinsic, i.e. undoped.

That an element or also a coat is arranged or extends above or below a longitudinal waveguide section or an (other) element or an (other) coat (that it is arranged or extends, in other words, above or below a longitudinal waveguide section or element or coat) includes both that it is directly on or directly under the longitudinal waveguide section or element or the coat, respectively, and is in contact therewith, for example with the upper or lower side of the longitudinal waveguide section or element or the coat, i.e. touches these, or also that something else, for example at least one further element or at least one further coat (above or also below), lies in between.

Furthermore, a passivation coat and/or a cladding can be provided above at least one of the active elements. A cladding is particularly suitable or embodied to make the index contrast somewhat lower, so that roughnesses on the sidewalls do not have quite such an effect; usually the losses go back into the waveguide(s). A passivation coat preferably serves the purpose of protecting the arrangement or circuit from environmental influences, in particular water. A passivation coat can, for example, consist of a dielectric material. Aluminium oxide (Al₂O₃) and silicon dioxide (SiO₂) have proven to be particularly suitable.

An upper, final passivation coat expediently has openings or interruptions to underlying contacts to enable an electrical connection. Openings or interruptions in a passivation coat can be or have been obtained, for example, by lithography and/or etching, in particular reactive ion etching.

The contact elements provided according to the invention are electrically conductive elements, which can also be understood as electrodes or represent such. They are expediently metallic, in particular comprise at least one metal, preferably titanium, nickel, palladium or aluminium, or consist of such a metal. In a preferred embodiment, the contact elements may comprise nickel and/or titanium and/or aluminium and/or copper and/or chromium and/or palladium and/or platinum and/or gold and/or silver, or consist of one or more of these metals. The contact elements may also comprise a plurality of layers, for example two or three layers. Then, each of the layers may comprise for example, of one or more of said metals or consist of one or more of said metals. In the case of multilayer contact elements, it may be further provided that the layers are configured differently. For example, the contact element or at least one of the contact elements or also each contact element may comprise one, for example upper, layer comprising or consisting of one metal or comprising or consisting of a combination of metals and another, for example lower, layer comprising or consisting of another metal or comprising or consisting of another combination of metals. For example, a layer of nickel and a layer of aluminium may be provided, or a layer of titanium and a layer of aluminium. In case of multiple layers, only one of the layers may be in contact with the active element or the active elements, for example a lower layer.

The contact elements are preferably used for the connection of or to a coaxial or coplanar conductor, wherein such a conductor is usually not brought into direct contact with the contact elements, but an interface or connection device for such a conductor, in particular for connection to such a conductor, can be used, which is then brought into contact with the contact elements. This may also serve as a sizing purpose, since the order of magnitude of the sizing of an electro-optical device according to the invention may significantly differ from the order of magnitude of the sizing of, for example, a conventional coaxial conductor, such as a coaxial cable or a coplanar conductor.

A coaxial conductor, such as a cable, is understood in a manner known per se to have an elongated inner conductor element and an outer conductor element of hollow cylindrical shape surrounding it, which is also referred to as a sheath. In particular, a coplanar conductor is to be understood as a conductor comprising an elongated inner conductor element and two elongated outer conductor elements arranged on either side of the inner conductor element, which outer conductor elements extend expediently parallel to the inner conductor element.

At least one of the contact elements can be or has been fabricated by deposition, in particular by chemical vapor deposition (CVD), preferably low-pressure chemical vapor deposition (LPCVD) and/or plasma-enhanced chemical vapor deposition (PECVD), and/or by physical vapor deposition (PVD) of a coating material. This can also apply to all contact elements.

There are various chemical vapor deposition processes known in the prior art, all of which can be or have been used in the context of the present invention. Common to all of them is usually a chemical reaction of introduced gases which leads to a deposition of the desired material.

Also with regard to physical vapor deposition, all variants known in the prior art have been or can be used. Purely by way of example, electron beam evaporation, in which material is melted and evaporated by means of an electron beam, as well as thermal evaporation, in which material is heated to the melting point by means of a heater and evaporated onto a target substrate, as well as sputter deposition, in which atoms are knocked out of a material carrier by means of a plasma and deposited onto a target substrate.

Alternatively or in addition to the above-mentioned deposition processes, atomic layer deposition (ALD) is also possible in order to obtain the gate electrode. In this process, insulating or conducting materials (dielectrics, semiconductors or metals) are sequentially deposited atomic layer by atomic layer.

A transfer process can also be used or has been used. This means, in particular, that the respective element(s) is/are/were not fabricated monolithically, for example on a chip or wafer, but is/are/were fabricated separately and then transferred. A transfer process for graphene is known, for example, from the papers “Large-Area Synthesis of High-Quality and Uniform Graphene Films on Copper Foils” from Li et al., Science 324, 1312, (2009) and “Roll-to-roll production of 30-inch graphene films for transparent electrodes” from Bae et al, Nature Nanotech 5, 574-578 (2010) or for LiNbO from the paper “Integrated lithium niobate electro-optic modulators operating at CMOS-compatible voltages”, Nature volume 562, pages 101104 (2018) or, inter alia, for GaAs from the paper “Transfer print techniques for heterogeneous integration of photonic components”, Progress in Quantum Electronics Volume 52, March 2017, pages 1-17. One of these processes can also be used in the context of the present invention to obtain one or more graphene or LiNbO or GaAs coats/films. A transfer process may be followed by structuring.

The aforementioned processes may also be used or have been used for obtaining the active element(s) and/or the longitudinal waveguide section of the respective interaction region(s) of an electro-optical device according to the invention.

In further development, it may be provided that at least one of the contact elements, preferably each of the contact elements, is associated with at least one interconnection element being in contact therewith. Via the interconnection element(s), for example, a connection to one or more integrated electronic components, such as transistors, for example from the front-end-of-line of a chip or wafer, can be achieved or realized. In this context, the term “connected” is to be understood as being connected in an electrically conductively manner.

In particular, an at least sectionally at least substantially U-shaped contact element is in a preferred embodiment associated with a plurality of interconnection elements with which the contact element is expediently in contact. For example, at least one interconnection element can be associated with each arm of such a contact element, with which interconnection element the respective arm is expediently in contact. In particular in addition, one or more interconnection elements may also be associated with the connecting section of such a contact element. Several contact elements can be provided for the purpose of establishing a preferably uniform ground potential. If a contact element is assigned a plurality of interconnection elements which are expediently in contact with the contact element, these are further preferably arranged at least substantially uniformly spaced from one another.

The interconnection element(s) are preferably vertical electrical connections, also known in English as Vertical Interconnect Access, or Via or VIA for short. VIAs are usually defined by lithography and dry-chemically etched, in particular by reactive ion etching (RIE). Afterwards, metallization is preferred and the metallized surface is structured by CMP (Damascene process) or by lithography and RIE. Reactive ion etching is a dry etching process in which selective and directional etching of a substrate surface is usually made possible by means of special gaseous chemicals that are excited to form a plasma. A resist mask can be used to protect parts that are not to be etched. The etch chemistry and the parameters of the process usually determine the selectivity of the process, i.e., the etch rates of different materials. This property is crucial for limiting the depth of an etching process and thus defining coats separately from each other.

The interconnection elements expediently comprise or consist of at least one electrically conductive material, in particular metal, such as copper and/or aluminium and/or tungsten. The interconnection elements may, for example, extend vertically through a chip or wafer or a substrate, in particular a semiconductor substrate, above which one or more electro-optical devices according to the invention are arranged. The longitudinal waveguide sections of these may be arranged, for example, on a substrate surface.

The active element or at least one of the active elements of the interaction region or of the respective interaction region is or has been expediently arranged relative to the longitudinal waveguide section of the interaction region or of the respective interaction region in such a way that it is exposed, at least in sections, to the evanescent field of electromagnetic radiation guided therewith. Preferably, the active element or at least one active element is arranged at a distance less than or equal to 50 nm, more preferably less than or equal to 30 nm, from the longitudinal waveguide section, for example at a distance of 10 nm.

The active element or at least one of the active elements is further preferably characterized by a longitudinal extension in the range of 5 to 500 micrometers.

The active element or at least one of the active elements extends at least in sections above and/or within a (respective) longitudinal waveguide section associated, in the latter case for example between two parts or segments thereof.

In case of waveguides, it applies that a part of the electromagnetic radiation, in particular of the light, is evanescently guided outside the waveguide. The interface of the waveguide is dielectric and accordingly the intensity distribution is described by the boundary conditions according to Maxwell with an exponential decay. If an electro-optically active material, for example graphene, is placed on or near the waveguide in the evanescent field, photons can interact with the material, in particular graphene.

There are four effects in graphene that lead to a photosignal. One is the bolometric effect, according to which the absorbed energy increases the resistance of the graphene and reduces an applied DC current. The change in DC current is then the photosignal. Another effect is the photoconductivity. Here, absorbed photons lead to an increase in the charge carrier concentration and the additional charge carriers reduce the resistance of the graphene because of the proportionality of the resistance to the charge carrier concentration. An applied DC current increases and the change is the photosignal. There is also a thermoelectric effect, according to which a thermoelectric voltage results from a pn-junction and a temperature gradient at this junction because of different Seebeck coefficients for the p and n regions. The temperature gradient results from the energy of the absorbed optical signal. This thermoelectric voltage is then the signal. The fourth effect is given by the fact that the excited electron-hole pairs are separated at a pn-junction. The resulting photocurrent is the signal.

In the case of a modulator, as explained above, an electrode, in particular an electrical control electrode, and an active element, suitably insulated therefrom, comprising or consisting of at least one electro-optically active material, in particular graphene, may be provided, or two active elements may be provided which, in operation, are together in the evanescent field and perform the electro-optical function. Graphene, for example, can change its optical properties by a control voltage. In the particularly advantageous case of a graphene-dielectric-graphene arrangement, a capacitance is created and the two films of graphene influence each other. A voltage charges the capacitance consisting of the graphene electrodes forming two active elements and the electrons occupy states in the graphene. This results in a shift of the Fermi energy (energy of the last occupied state in the crystal) to higher energies (or to lower ones due to symmetry). When the Fermi energy reaches half the energy of the photons, they can no longer be absorbed because the free states required for the absorption process are already occupied at the correct energy. Consequently, in this state, the graphene is transparent because absorption is forbidden. By changing the voltage, the graphene is switched back and forth between absorbing and transparent. A continuously shining laser beam is modulated in its intensity and can thus be used for information transmission. Likewise, the real part of the refractive index changes with the control voltage. By changing the voltage, the phase position of a laser can be modulated via the changing refractive index and thus phase modulation can be achieved. Preferably, the phase modulation is operated in a range in which all states are occupied up to above half the photon energy, so that the graphene is transparent and the real part of the refractive index shifts significantly and the change in absorption plays a minor role.

A waveguide or a longitudinal waveguide section is a component that guides an electromagnetic wave, such as light, and is designed accordingly for this purpose. In order to guide the wave, a cross-section of an optically transparent material, which depends on the wavelength and is distinguished from an adjacent material, which is also transparent for this waveguide, by a refractive index contrast, is expediently provided. If the refractive index of the surrounding material is lower, the light is guided in the region of higher refractive index. For the particular case of a slit mode, two regions of high refractive index are separated from a region of low refractive index, which is narrow with respect to the wavelength, and the light is guided in the region of low refractive index. To achieve low losses due to scattering, a low sidewall roughness is advantageous.

Usually, one or more waveguides is/are provided—for example on a chip or a wafer. As a rule, only a longitudinal section of a waveguide will be part of an electro-optical device according to the invention, for example a longitudinal section extending below an active element thereof. However, it is of course also not excluded that a waveguide is considered to be part of an electro-optical device according to the invention over its entire longitudinal extent. In other words, in addition to the longitudinal section of a waveguide extending in particular below an active element such a device may also comprise the remainder of such a waveguide.

A waveguide can be designed, for example, as a strip waveguide, which is characterized, for example, by a rectangular or square cross-section. A waveguide may alternatively or additionally be formed as a ridge waveguide with a T-shaped cross-section. Further alternatively or additionally, it is possible that a waveguide is given by a slot waveguide having at least one gap.

A waveguide or a longitudinal section of such a waveguide may further comprise several sections or segments when viewed in cross-section and be formed in several parts, such as comprising or consisting of a first, for example lower or left, segment and a second, for example upper or right, segment. For example, a slot waveguide or a longitudinal section of such, may have a left and right segment between which the slot or gap is formed. It may be that one or more waveguide segments are characterized by a rectangular or square cross-section. It is also possible that a waveguide (longitudinal section) or one or more segments thereof is characterized, at least in sections, by a tapering cross-section and/or, at least in sections, by a widening cross-section. If there are a several segments, these may be arranged at a distance from each other as well as be directly adjacent to each other and in contact with one another, for example because one segment has been fabricated directly on top of another segment.

As regards the dimensions of the longitudinal waveguide section and/or the further longitudinal waveguide section, the following may apply, for example. The thickness may be in the range of 150 nm to 10 μm, for example. In particular, the width and length may be in the range of 100 nm and 10 μm.

In an expedient embodiment, the longitudinal waveguide section(s) comprise(s) or consist(s) of at least one material that is transparent to electromagnetic radiation of a wavelength of 850 nm and/or 1310 nm and/or 1550 nm. Particularly preferably, it is transparent to electromagnetic radiation in the wavelength range from 800 nm to 900 nm and/or from 1260 nm to 1360 nm (so-called original band or O-band for short) and/or 1360 nm to 1460 nm (so-called extended band or E-band for short) and/or 1460 nm to 1530 nm (so-called short band or S-band for short) and/or 1530 nm to 1565 nm (so-called conventional band or C-band for short) and/or 1565 nm to 1625 nm (so-called long band or L-band for short). These bands are known from the field of communications engineering.

As a material for waveguides, for example, the following have proven to be particularly suitable: Titanium dioxide and/or aluminium nitride and/or tantalum pentoxide and/or silicon nitride and/or aluminium oxide and/or silicon oxynitride and/or lithium niobate and/or silicon, in particular polysilicon, and/or indium phosphite and/or gallium arsenide and/or indium gallium arsenide and/or aluminium gallium arsenide and/or at least one dichalcogenide, in particular two-dimensional transition metal dichalcogenide, and/or chalcogenide glass and/or heterostructures of two-dimensional materials and/or resins or materials containing resins, in particular SUB, and/or polymers or polymer-containing materials, in particular OrmoClad and/or OrmoCore. In this context, the longitudinal waveguide section and/or the further longitudinal waveguide section may comprise one or more of these materials, or may also consist of one of these materials or of a combination of two or more of these materials.

If the respective longitudinal waveguide section or sections has/have several segments when viewed in cross-section, these may all comprise the same material(s) or consist of the same material(s). However, it is of course also possible that two or more segments differ with respect to their material(s). For example, at least one segment may be characterized by a refractive index that is greater than the refractive index of at least one other segment. For example, if several segments are sandwiched or stacked, the outer segments may have a lower refractive index. Then the light is bundled in the center of the waveguide arrangement. Purely as an example of associated materials, an upper and lower segment consisting of aluminium oxide with a middle segment consisting of titanium oxide between them may be mentioned.

Different materials of the segments may also be advantageous for the reason that they are characterized by different etch rates. This may offer advantages in the context of fabrication, such as for required structuring.

The longitudinal waveguide section of the interaction region or the respective interaction region further preferably comprises at least one material whose refractive index differs from the refractive index of a material surrounding it, or it comprises at least one such material.

If the longitudinal waveguide section of the interaction region or of the respective interaction region is one that comprises two or more segments, at least two of which are spaced apart form a gap, it may be advantageously provided that the gap is filled with at least one dielectric material whose refractive index is smaller than the refractive index of the material of the waveguide segments defining the gap.

As purely exemplary pairs of refractive indices in such a case, 3.4 (Si) for the longitudinal waveguide section and/or the further longitudinal waveguide section and 1.5 (SiO₂) for the surrounding material or, in the case of dielectrics, 2.4 (TiO₂) for the longitudinal waveguide section and/or the further longitudinal waveguide section and 1.5 (SiO₂) for the surrounding material or 2 (SiN) for the longitudinal waveguide section and/or the further longitudinal waveguide section and 1.47 for the surrounding material may be mentioned.

It is particularly preferred that the refractive index of the longitudinal waveguide section of the interaction region or of the respective interaction region is at least 20%, preferably at least 30%, greater than the refractive index of the surrounding material.

The longitudinal waveguide section of the interaction region or of the respective interaction region and/or the active element or at least one of the active elements may further be arranged above, preferably on a coat, for example a coat comprising or consisting of at least one dielectric material, for example silicon dioxide. The active element or one of the active elements may, for example, be arranged on a coat, which is provided above, in particular on the longitudinal waveguide section, and has been optionally fabricated on the longitudinal waveguide section, optionally also fabricated on the coat. In particular, a coat comprising or consisting of a dielectric material provided between a longitudinal waveguide section and an active element may, for example, have a thickness in the range of up to 50 nm, preferably up to 30 nm, particularly preferably 10 to 20 nm.

It can be a planarization coat, which is preferably characterized, at least in sections, by a roughness in the range from 1.0 nm RMS to 0.1 nm RMS, in particular 0.6 nm RMS to 0.1 nm RMS, preferably 0.4 nm RMS to 0.1 nm RMS, on that side above which or on which the respective longitudinal waveguide section or the respective active element is arranged. The abbreviation nm stands for nanometer (10⁻⁹ m) in a manner known per se.

Roughnesses in the ranges mentioned can be or have been obtained, for example, by chemical mechanical polishing (CMP) and/or resist planarization.

In chemical-mechanical polishing, an object to be polished is usually polished by a rotating movement between grinding pads. The polishing is performed chemically on the one hand and physically on the other hand by means of an abrasive paste. By combining the chemical and physical action, smooth surfaces can be obtained in a sub-nm scale.

In particular, resist planarization includes a single or repeated spin-on-glass deposition and subsequent etching, preferably reactive ion etching (RIE). If a surface, such as a SiO₂ surface, which has height differences, is to be planarized, this can be done by spin-on-glass deposition and etching. The spin-on-glass coat partially compensates for the height differences, i.e. valleys of the topology have a higher coat thickness after spin-on-glass coating than adjacent elevations. The etch rate of spin-on-glass and, for example, SiO₂ is similar or the same in an adapted RIE process. Adapted here means, in particular, that the pressure, the gas flow, the composition of the gas mixture and the power are selected accordingly. If the entire spin-on-glass coat is etched by RIE after spin-on-glass coating, the height difference has been reduced due to the planarizing effect of the spin-on-glass coat. The height difference can be further reduced by repetition. The consumed SiO₂ coat thickness must be taken into account when depositing the SiO₂ coat, so that the desired SiO₂ coat thickness is achieved after completing the final etching step. It should be emphasized that resist planarization is not limited to SiO₂, but can also be considered for other materials. It is convenient if an etch rate of the material can be achieved that is similar to, or at least substantially the same as, that of spin-on-glass. For SiO₂ and spin-on-glass, this condition is met. It should be noted that, for example, materials whose etch rate differs from that of spin-on-glass by a factor of 2 are also possible, in which case several passes are usually necessary. Hydrogen silsesquioxane and/or a polymer, for example, can be applied as a liquid material, in particular spun on. It vitrifies during subsequent annealing, which is why it is also referred to as spin-on glass. Hydrogen silsesquioxane (HSQ for short) is a class of inorganic compounds with the formula [HSiO_{3/2}]ₙ. Resist planarization is also described in the earlier German patent application with file number 10 2020 102 533.5, which also goes back to the applicant.

Roughnesses in the aforementioned ranges have proven to be particularly suitable. They are particularly advantageous for avoiding stress and tension in overlying coats. In this context, reference should also be made to the paper “Identifying suitable substrates for high-quality graphene-based heterostructures” from L. Banszerus et al, 2D Materials, vol. 4, no. 2, 025030, 2017.

Atomic force microscopy (AFM) can be used as a measurement method for determining the roughness, in particular as described in the EN ISO 25178 standard. Atomic force microscopy is mainly discussed in Part 6 (EN ISO 25178-6:2010-01) of this standard, which deals with measurement methods for roughness determination.

In particular, for an electro-optical device according to the invention formed as a modulator, it may further be provided that it comprises a diode or a capacitor. It may then be, for example, an integrated III-V semiconductor modulator as described in the paper “Heterogeneously integrated III-V/Si MOS capacitor Mach-Zehnder modulator” from Hiaki, Nature Photonics volume 11, pages 482-485 (2017).

If a diode has been or is provided, it may comprise, for example, a plurality of coats of different compositions of, for example, InGaAsP, in particular to create a pn-junction and two contact regions.

The invention also relates to an electro-optical arrangement comprising at least one electro-optical device according to the invention and a connection device for connecting to a coaxial and/or coplanar conductor, wherein the connection device comprises one or more inner connection contact elements serving as ground contact and one or more outer connection contact elements serving as a signal contact, and wherein the inner contact element(s) of the electro-optical device is/are or can be connected to the inner connection contact element(s) of the connection device, and wherein the outer contact element(s) of the electro-optical device is/are or can be connected to the outer connection contact element(s) of the connection device.

It is further an object of the invention to provide a semiconductor apparatus comprising a chip and at least one, preferably a plurality of electro-optical devices according to the invention, in particular photodetectors and/or modulators, wherein the device or the devices are preferably being arranged on the chip or on a coat arranged above the chip.

In a particularly preferred embodiment, the electro-optical device or the respective electro-optical device according to the invention is part of a photonic platform fabricated on the chip or bonded to the chip.

A further object of the invention is a semiconductor device comprising a wafer and at least one, preferably a plurality of devices according to the invention, in particular photodetectors and/or modulators, wherein the device or devices are preferably arranged on the wafer or on a coat arranged above the wafer.

The device or the respective device may in particular be part of a photonic platform fabricated on the wafer or bonded to the wafer.

By bonded it is to be understood preferably that the photodetector(s) and/or modulator(s) are not or have not been fabricated on or above the chip or wafer but separately therefrom and are or have been bonded to the chip or wafer after their fabrication—possibly also as part of a larger unit—for example using a suitable intermediate coat.

If a chip or wafer is viewed in cross-section, its vertical structure can be divided into different sub-regions. The lowest part is the front-end-of-line, or FEOL for short, which usually comprises one or more integrated electronic components. The integrated electronic component(s) may be, for example, transistors and/or capacitors and/or resistors. Above the front-end-of-line is the back-end-of-line, or BEOL for short, which usually contains various metal planes by means of which the integrated electronic components of the FEOL are interconnected.

A wafer comprises a plurality of regions which, following dicing/fragmenting/unification, each form a chip or die. These regions are also referred to herein as chip or die regions. Each chip region of the wafer preferably comprises a section or partial region of the, in particular, single-piece semiconductor substrate of the wafer. Preferably, each chip region further comprises one or more integrated electronic components extending in and/or on the corresponding region of the semiconductor substrate—in particular in the FEOL when viewed in cross-section. It should be emphasized that the chip regions do not represent isolated chips, i.e., the wafer does not comprise isolated chips.

Both, a semiconductor apparatus according to the invention and a semiconductor device according to the invention may comprise a plurality of electro-optical devices according to the invention, in particular photodetectors and/or modulators, which are identical in design, or a plurality of electro-optical devices according to the invention, in particular photodetectors and/or modulators, which are different in design. There may also be some identical electro-optical devices and additionally one or more electro-optical devices according to the invention which are different therefrom.

Furthermore, in the case that one or more electro-optical devices according to the invention are arranged on a chip or wafer, one or more connection devices for connection to a coaxial and/or coplanar conductor can of course also be provided. These may then also be arranged on the wafer/chip or on a coat arranged above the wafer/chip. In other words, it may also be the case that a semiconductor apparatus or semiconductor device according to the invention comprises one or more electro-optical devices according to the invention. Alternatively, the connection devices may be arranged separately to the chip or wafer.

Finally, the invention relates to the use of an electro-optical device according to the invention in such a way that the inner contact element or the inner contact elements of the electro-optical device is/are connected to the ground contact(s) of a coaxial or coplanar conductor or of a connection device for connecting to a coaxial or coplanar conductor, and that the outer contact element(s) of the electro-optical device is/are connected to the signal contact(s) of a coaxial or coplanar conductor or of a connection device for connection to a coaxial or coplanar conductor.

The electrically conductive connection between the respective electro-optical device(s) and the respective connection device(s) may be realized, for example, by wires or by means of bonding.

With regard to the embodiments of the invention, reference is also made to the subclaims as well as to the following description of several embodiments with reference to the accompanying drawing.

In the drawing shows

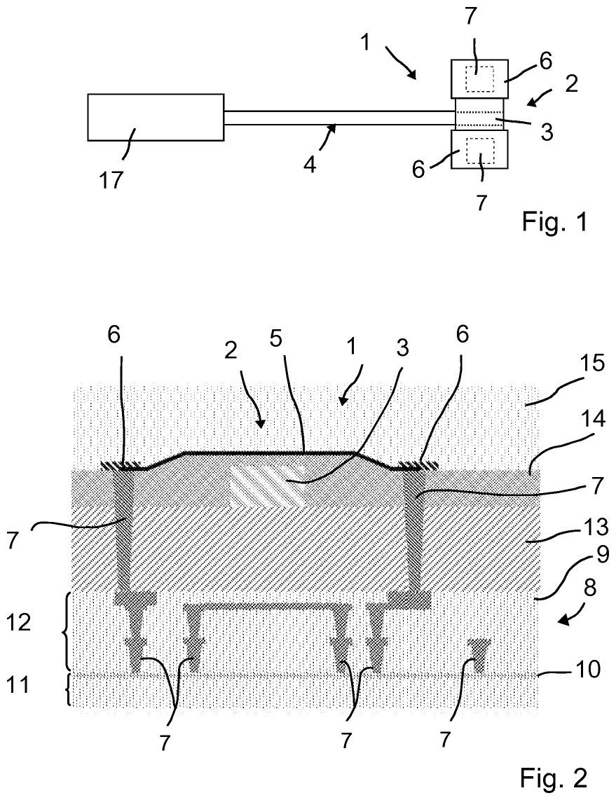

FIG. 1 a top view of a photodetector according to the prior art;

FIG. 2 a partial section through a semiconductor device with the photodetector of FIG. 1;

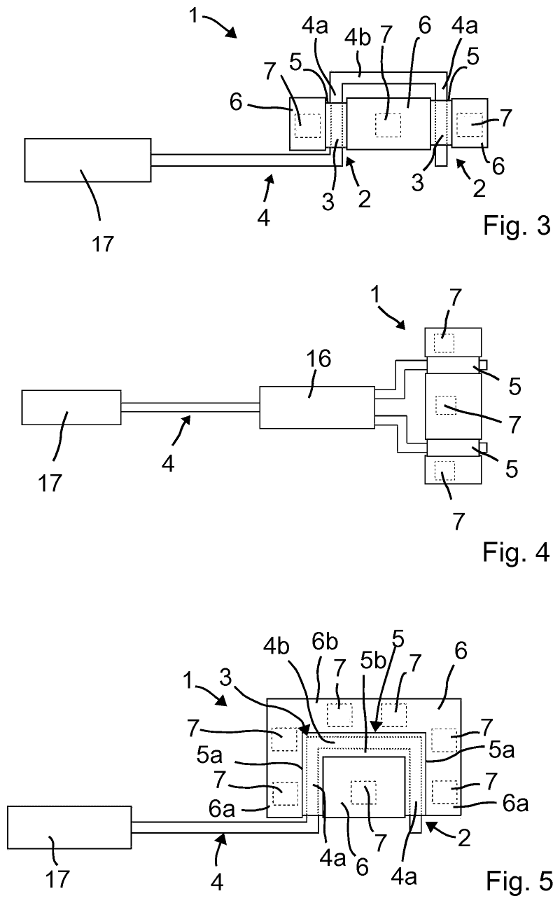

FIG. 3 a top view of an embodiment of an electro-optical device according to the invention, which is formed as a photodetector according to the first aspect of the invention and comprises two interaction regions;

FIG. 4 a top view of an embodiment of an electro-optical device according to the invention, which is formed as a photodetector according to the first aspect of the invention and comprises a waveguide with a bifurcation and two interaction regions;

FIG. 5 a top view of an embodiment of an electro-optical device according to the invention, which is formed as a photodetector according to the second aspect of the invention and comprises a U-shaped interaction region;

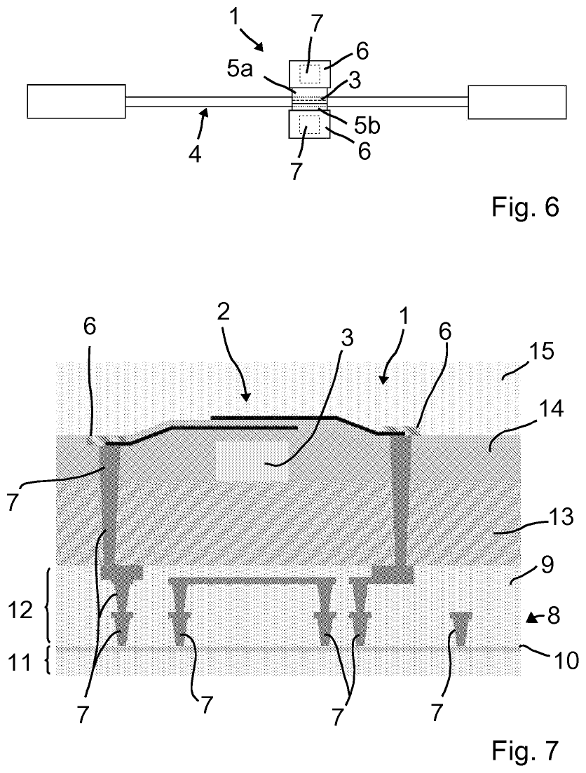

FIG. 6 a top view of an electro-optical modulator according to the prior art;

FIG. 7 a partial section of a semiconductor device with the electro-optical modulator of FIG. 6;

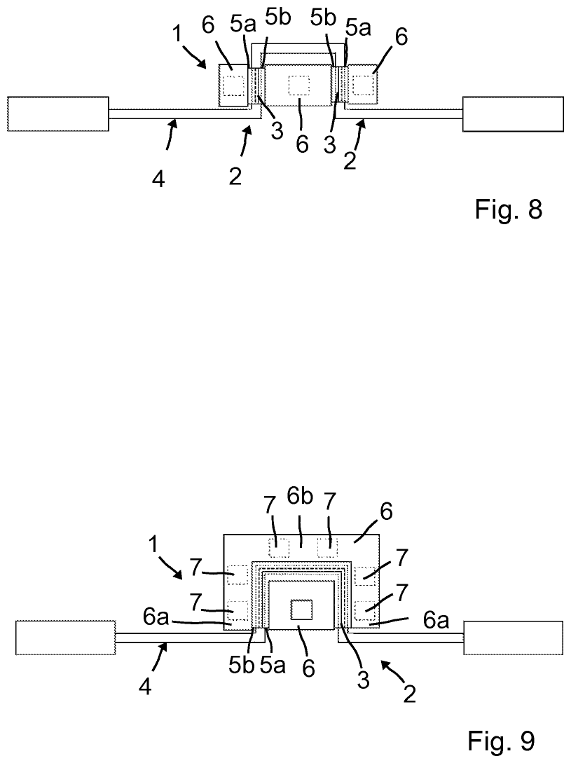

FIG. 8 a top view of an embodiment of an electro-optical device according to the invention, which is formed as an electro-optical modulator and comprises two interaction regions;

FIG. 9 a top view of an embodiment of an electro-optical device according to the invention, which is formed as an electro-optical modulator and comprises a U-shaped interaction region;

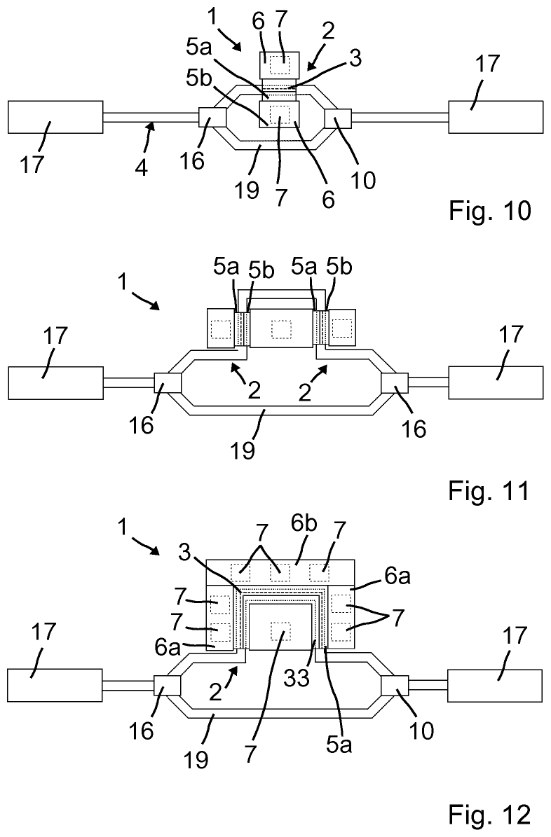

FIG. 10 a top view of a Mach-Zehnder interferometer with an electro-optical modulator according to the prior art;

FIG. 11 a top view of an embodiment of a Mach-Zehnder interferometer according to the invention, which comprises an electro-optical modulator with two interaction regions;

FIG. 12 a top view of an embodiment of a Mach-Zehnder interferometer according to the invention, which comprises an electro-optical modulator according to the invention with two interaction regions, in a purely schematical representation;

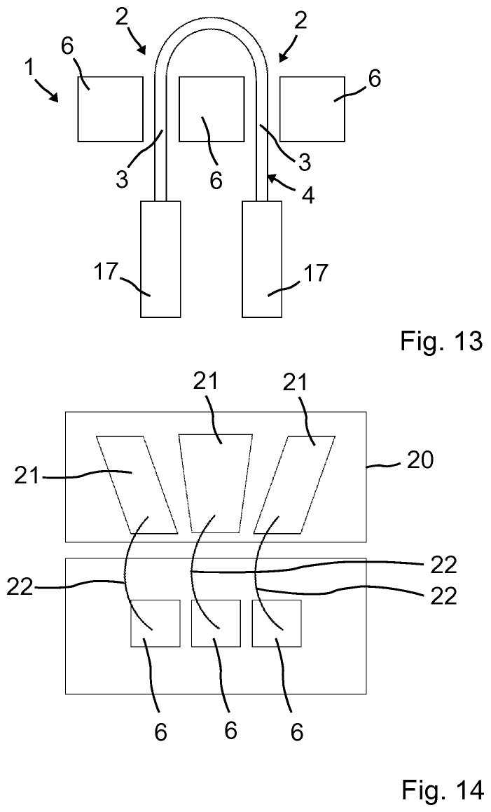

FIG. 13 a top view of a further embodiment of an electro-optical device according to the invention, which can be formed as a photodetector or as an electro-optical modulator;

FIG. 14 a top view of three contact elements of an embodiment of an electro-optical device according to the invention, which are connected by means of wires to a connection device for a coaxial cable; and

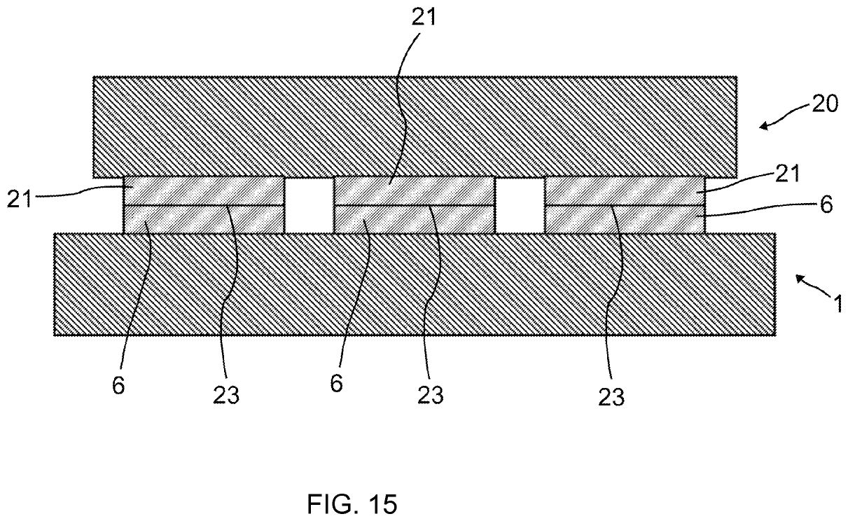

FIG. 15 a sectional view showing components of an embodiment of an electro-optical device according to the invention, the contact elements of which are connected to connection device for a coaxial cable by a bonding layer.

All figures show purely schematic representations. In the figures, the same components or elements are provided with the same reference signs.

FIG. 1 shows a top view of an electro-optical device 1 according to the prior art, which is designed as a graphene-based photodetector. FIG. 2 shows a section of the detector. It comprises an interaction region 2 with a longitudinal section 3 of a waveguide 4 and an active element 5 in the form of a graphene film. As can be seen, the active element 5 extends in sections above the longitudinal waveguide section 3, specifically overlapping it at the right-hand end of the waveguide 4. Since the active element 5 obscures the underlying longitudinal waveguide section 3 in plan view, the latter is shown in the figure with dashed lines. In the present case, the waveguide 4 and, thus, the longitudinal section 3 thereof belonging to the interaction region 2 consists of titanium dioxide, whereby this is to be understood purely by way of example.

The active element 5 is characterized by a greater width than the longitudinal waveguide section 3, so that it projects beyond the latter on both sides. On its sides lying laterally of the longitudinal waveguide section 3, the active element 5 is in contact in each case with one of two metallic contact elements 6 arranged on both sides of the longitudinal waveguide section 3. The contact elements 6 may comprise, for example, nickel and/or titanium and/or aluminium and/or copper and/or chromium and/or palladium and/or platinum and/or gold and/or silver or consist of one or more of these metals. It may be that the contact elements comprise several layers, which may comprise or consist of different metals.

Each of the two contact elements 6 associated with the interaction region 2 and in contact with the active element 5 is associated with a respective interconnection element 7 with which the respective contact element 6 is in contact, specifically on its underside. In other words, the respective contact element 6 connects the respective active element 5 to an interconnection element 7. Since the interconnection elements 7 are concealed by the contact elements in the top view, they are shown with dashed lines. The interconnection elements 7 are vertical electrical connections, which are also referred to in English as Vertical Interconnect Access, Via or VIA for short. The interconnection elements are—just like the contact elements—metallic, for example consist of copper, and extend in the vertical direction through a chip or a wafer or a substrate, in particular a semiconductor substrate, of a chip or a wafer, above which, in particular on which, the photodetector 1 is provided. In the present case, the detector 1 is located above a wafer 8 of a semiconductor device, a partial section of which is shown in FIG. 2. In the present case, wafer 8 comprises a single-piece silicon substrate 9 and a plurality of integrated electronic components 10, which, in the embodiment shown, extend in the semiconductor substrate 9. The integrated electronic components 10, which may in particular be transistors and/or resistors and/or capacitors, are only indicated in simplified form in the schematic FIG. 2 by a hatched line provided with the reference sign 10. At a corresponding position in the substrate 9, a large number of integrated electronic components 10 are found in a sufficiently known manner. These can also be components of processors, such as CPUs and/or GPUs, or form such components in a likewise known manner.

The wafer 8 has a front-end-of-line (FEOL for short) 11, in which the plurality of integrated electronic components 10 are arranged, and a back-end-of-line (BEOL for short) 12, lying there above, in which or via which the integrated electronic components 10 of the front-end-of-line 11 are interconnected by means of different metal planes. The integrated electronic components 10 in the FEOL 11 and the associated interconnection in the BEOL 12 form integrated circuits of the wafer 8 in a sufficiently known manner. A FEOL 11 is sometimes also referred to as transistor front-end and a BEOL 12 as a metal back-end. The metal planes comprise a plurality of further interconnection elements 7, which are presently given by VIAs.

On the wafer 8 there is a coat 13 of a dielectric material, presently silicon dioxide (SiO₂) on which the waveguide 4 is located. There is also a further dielectric coat 14 on the waveguide 4 and the coat 13, on which the active element 5 is arranged.

An upper passivation coat 15 is still provided on the active element 5, which preferably consists of Al₂O₃ and/or SiO₂.

The waveguide 4, the active element 5, the contact elements 6, the interconnection elements 7 and the coats 13, 14, 15 may have been obtained in a manner known from the field of chip or a wafer fabrication, for example by (multilayer) material deposition or a transfer process and possibly structuring.

In the embodiment shown, either the dielectric coat 13 or the dielectric coat 14 or both of these coats are designed as planarization coats, which are characterized by a roughness in the range of 1.0 nm RMS to 0.1 nm RMS, in particular 0.6 nm RMS to 0.1 nm RMS, preferably 0.4 nm RMS to 0.1 nm RMS. The abbreviation nm stands in a manner known per se for nanometer (10⁻⁹ m). Roughnesses in these ranges can be or have been obtained, for example, by chemical mechanical polishing (CMP) and/or resist planarization, as also described in the earlier German patent application with file number 10 2020 102 533.5, which also goes back to the applicant. As can be seen, a connection to one or more of the integrated electronic components 10 is realized via the interconnection elements 7 connected to the contact elements 6 of the photodetector 1 and the interconnection elements 7 from the wafer 8.

The shown photodetector 1 serves in a manner known per se for signal conversion back from the optical to the electronic world. In other words, a light signal conducted through the waveguide 4 can be converted into an electrical signal.

The active element is arranged relative to the longitudinal waveguide section 3 of the interaction region 2 in such a way that it is exposed, at least in sections, to the evanescent field of electromagnetic radiation guided in the waveguide 4 and thus the longitudinal section in operation, so that an interaction can take place. In the present case, the distance between the upper surface of the longitudinal waveguide section 4 and the lower surface of the overlying section of the active element 5 is about 10 nm.

FIG. 3 shows a top view of an embodiment of an electro-optical device according to the invention, which is also designed as a photodetector 1. It is characterized—in contrast to the pre-known photodetector according to FIG. 1—by a G-S-G-configuration.

In concrete terms, it has two interaction regions 2, each comprising a longitudinal waveguide section 3 and an active element 5, which comprises or consists of at least one electro-optically active material, in particular graphene. In the shown embodiment, the active element 5 of the device according to the invention is also given by a graphene film 13. However, it should be emphasized that according to the invention it is also possible for the active element 5 to be given by a film comprising or consisting of at least one other or further electro-optically active material, for example a film comprising or consisting of a dichalcogenide-graphene heterostructure consisting of at least one layer of graphene and at least one layer of a dichalcogenide, or by a film comprising at least one layer of boron nitrite and at least one layer of graphene.

The two longitudinal waveguide sections 3 of the two interaction regions 2 of the photodetector of FIG. 3 are spaced apart from each other. They are part of a waveguide 4. The waveguide 4 is characterized in sections by an at least substantially U-shaped course with two rectilinear arms 4a, which are spaced apart from one another and extend at least substantially parallel to one another and a rectilinear connecting section 4b, which connects the two arms 4a, and in each case one of the two longitudinal waveguide sections 3 lies in the region of one of the arms 4a.

In analogy to the previously known detector from FIG. 1, it applies to the two active elements 5 here that they extend at least in sections above the longitudinal waveguide section of the respective interaction region 2.

Furthermore, not only two but a total of three contact elements 6 are provided, each of which is in contact with at least one of the active elements 5. Specifically, an inner contact element 6 is provided, which is arranged between the two spaced-apart longitudinal waveguide sections 3 and serves as an inner signal contact, and two outer contact elements 6 are provided, which are each arranged on the other side of the respective longitudinal waveguide section 3 with respect to the inner contact element 6 and each serve as an outer ground contact. The inner contact element 6 is in contact both with the active element of one of the two interactional regions 2 and with the active element 5 of the other of the two interaction regions 2. For the two outer contact elements 6, it applies that one is in contact with the active element 5 of one interaction region 2 and the other is in contact with the active element 5 of the other interaction region 2.

As can be seen, the inner contact element 6 and the two outer contact elements 7 lie on a line and are aligned with each other. They form a symmetrical G-S-G contact arrangement with an inner signal contact and two outer ground contacts enclosing the inner signal contact. As a result, a symmetrical arrangement with respect to ground and signal and thus a very advantageous arrangement is given, from which high-frequency signals can be transmitted more interference-free to coaxial arrangements, which will be discussed further below.

While the U-shaped waveguide section is very well suited to provide a space for the inner signal contact, there can be a disadvantage associated with it in terms of the symmetry of the electrical signal. According to Lam bert-Beer's law, the absorption of the electromagnetic radiation along the propagation direction causes more to be absorbed in the active element(s) in the region of the first arm 4a in the direction of light propagation, i.e. the left arm 4a in FIG. 3, than in the active element 5 of the second arm 4a, the right arm in FIG. 3. Then the high-frequency mode can be asymmetrically excited in an unfavorable manner. This problem is prevented by the fact that the waveguide cross-section in the U-shaped region of the waveguide 4 is specifically adapted in such a way that the interaction of the light per length along the propagation direction with the active elements 5 in the first arm 4a is just so much less in comparison to the second arm 4a that the absorbed power in both arms 4a is just identical. For this purpose, the waveguide cross-section in the first, left arm 4a is wider than in the second, right arm 4a. Thus, the optical mode in the first arm 4a is guided further inside the waveguide 4, reducing the interaction in the first arm 4a. In other words, the cross-sectional area in the region of the first, left arm 4a of the U-shaped waveguide section is larger than the cross-sectional area in the region of the second, right arm 4a. The ratio is chosen in such a way that half the power of the incident light is absorbed in the first, left arm 4a.

Apart from the fact that the detector 1 according to the invention of FIG. 3 has a waveguide with a U-shaped section and a second interaction region 2 with a second longitudinal waveguide section 3 and a second active element 5 as well as a third contact element, it can otherwise correspond to that according to FIG. 1. In particular, as far as the materials and the fabrication possibilities mentioned above in relation to FIG. 1 are concerned, there can be conformity with the arrangement of FIG. 1 or there is conformity. The detector 1 according to the invention in FIG. 3 is also arranged above a wafer 8 and a dielectric coat 13, and coats 14 and 15 are present, so that in this respect there is conformity with FIG. 2. In other words, in the embodiment shown, the detector 1 according to the invention is integrated in a semiconductor device comprising a wafer 8. This semiconductor device is an embodiment of a semiconductor device according to the invention. Such a device may comprise a plurality, for example several ten, several hundreds or even several thousands, of electro-optical devices according to the invention, which may be identical in design of different. From a semiconductor device according to the invention with a wafer 8, a plurality of semiconductor apparatuses according to the invention can be obtained by dicing, which is sufficiently known from the prior art, which semiconductor apparatus each can comprise a chip and one or more electro-optical devices according to the invention. The electro-optical device(s) according to the invention may be components of an integrated photonic platform.

Alternatively to a design in which the two spaced longitudinal waveguide sections 3 of the two interaction regions 2 may be located in the region of the two arms 4a of a U-shaped waveguide section, a bifurcation may also be provided. An embodiment of a corresponding photodetector 1 is shown in FIG. 4 in top view. As can be seen, the waveguide 4 comprises a bifurcation with two branching arms 4c, 4d and one of the longitudinal waveguide sections 3 of each of the two interactional regions 2 lies in the region of one arm 4c, 4d of the bifurcation here. Alternatively to space being provided within a U-shaped waveguide section for at least one inner contact element 7 serving as a signal contact, the space is provided here between the two bifurcation arms 4c, 4d. A splitter 16 is also provided with which an incoming light signal can be distributed to the two arms 4c, 4d of the bifurcation, namely in equal proportions. It is therefore a 50/50 splitter. The splitter can, for example, be designed as an MMI splitter or a directional coupler or comprise such a coupler.

The design with a bifurcation offers the advantage of symmetrical absorption. A different waveguide cross-section in the two arms 4c, 4d is therefore not necessary.

An embodiment of a photodetector 1 according to the second aspect of the invention is shown in FIG. 5. In contrast to the two embodiments shown in FIGS. 3 and 4, this embodiment does not comprise two separate interaction regions spaced apart from each other, but a continuous, at least substantially U-shaped interaction region 2. This interaction region 2 has—in analogy to FIG. 3—an at least substantially U-shaped longitudinal waveguide section 3 with two spaced-apart arms 4a and a connecting section 4b connecting the two arms 4a, and a likewise at least substantially U-shaped active element 5 with two spaced-apart arms 5a and a connecting section 5b connecting the two arms 5a. The longitudinal waveguide section 3 is, as can be seen, part of a waveguide 4, which is not annularly closed, but open.

The U-shaped active element 5 again comprises or consists of at least one electro-optically active material. In the embodiment according to FIG. 5, the active element 5 is also provided by a graphene film, whereby this is again to be understood purely by way of example. The active element extends in sections above the longitudinal waveguide section 3. Two contact elements 6 are also provided, each of which is in contact with the active element 5. Exactly one inner contact element 6 is provided, which is arranged inside the at least sectionally at least substantially U-shaped longitudinal waveguide section 3 and serves as an inner signal contact, and exactly one outer contact element 6 is provided, which is at least substantially U-shaped with two arms 6a spaced apart from one another and a connecting section 6b connecting the two arms 6a, and surrounds the U-shaped longitudinal waveguide section 3 on the outside. The two arms 6a of the outer contact element 6 each serve here, at least in sections, as an outer ground contact. As can be seen, the U-shaped outer contact element 6 completely surrounds the U-shaped active element 5, in other words over the entire extent of the U. The U-shaped longitudinal waveguide section 3 is almost completely embraced or enclosed.

Not only is there one interconnection element 7 associated with the outer U-shaped contact element, but this is in contact with a total of six such elements on the underside, as can be seen. A particularly uniform ground potential can be established via the several interconnection elements 7. The interconnection elements 7 are expediently arranged at a distance from each other, in particular evenly distributed over the extent of the outer contact element 6.

For the sake of completeness, it should be noted that it is of course possible that in the embodiment in FIG. 3, instead of the two separate outer contact elements 6, a continuous outer contact element 6 could be provided, which surrounds or encloses the U-shaped waveguide sections on the outside. For example, the U-shaped outer contact element 6 of FIG. 5 could be used with the detector 1 of FIG. 3. In an analogous manner, it is in principle possible that in the embodiment shown in FIG. 5, instead of the one U-shaped outer contact element, two separate outer contact elements 6 are provided, as shown in FIG. 3.

Also, in the embodiment shown in FIG. 5, it is preferably the case that the cross-sectional area of the waveguide 6 is larger in the region of the first, left arm 4a than in the region of the second, right arm 4a, in particular in such a way that half the power is absorbed in the first arm, for the same reasons as explained above in connection with FIG. 3. For the coupling of light into waveguide 4, a coupling device 17 is provided in each case, which is located at the left-hand end of the waveguide 4 in FIGS. 1, 3, 4 and 5. The modulator 1 is located at the other end of the waveguide 4, which is on the right hand side in each case in the figures. The waveguide ends behind the modulator respectively.

Alternatively to an electro-optical device 1 according to the invention being designed as a photodetector, such a device can also be an electro-optical modulator, for example. In that case, it differs from a photodetector substantially in that the interaction region or the respective interaction region comprises two active elements 5 or one active element 5 and a (conventional) electrode, for example comprising or consisting of titanium nitrite or indium tin oxide.

Examples of electro-optical modulators according to the invention can be taken from FIGS. 8 and 9. FIG. 6 shows—in analogy to FIG. 1—a top view of a conventional electro-optical modulator as known from the prior art. FIG. 7 shows a sectional view of the modulator from FIG. 6. In analogy to FIG. 2, this again is a component of a semiconductor device with a wafer 8.

As can be seen in particular in the sectional view in FIG. 7, the two active elements 5a, 5b are spaced apart from one another in the vertical direction and one active element 5a extends in sections above the other active element 5b. The distance can be 1 nm, for example. A further coat 18 comprising or consisting of a dielectric material is provided between the two active elements 5a, 5b, the thickness of which between the two active elements 5a, 5b is corresponding.

The two active elements 5 are furthermore, as can be seen well in the sectional view, arranged offset to each other in the horizontal direction in such a way that they lie one above the other in an overlap region in sections (with spacing in the vertical direction). The overlap region is located above the longitudinal waveguide section. For the embodiment according to the invention as shown in FIG. 8, it applies that in both interaction regions 3 the active elements are arranged correspondingly to each other and relative to the longitudinal waveguide section 3. For the embodiment according to FIG. 9, this applies to one U-shaped interaction region 2, namely over its entire extent. In the top views from FIGS. 6, 7 and 8 (and also FIGS. 10 to 12) the offset and sectional overlap of the active elements 5 is indicated by corresponding dashed lines.

In case of a modulator with two active elements or one active element and one electrode in the respective interaction region, it is expedient that the inner contact element or one of the inner contact elements 6 is in contact with the active element 5a of the interaction region or of the respective interaction region and the outer contact element or one of the outer contact elements 6 is in contact with the other active element 5b or the electrode of the interaction region or of the respective interaction region 2, or vice versa.

In the embodiment of FIG. 8, which corresponds in its remaining construction to that of FIG. 3, the inner contact element 6, arranged between the two longitudinal waveguide sections 3 of the two interaction regions 2, is in contact with an active element 5a, 5b of both interaction regions 2, specifically on opposite sides. With regard to the two outer contact elements 6, it applies here that these are each in contact with only one active element 5a, 5b of an interaction region 2.

In the embodiment in FIG. 9 with only one continuous, U-shaped interaction region 2, which corresponds in its other structure to that in FIG. 5, the inner contact element 6 is in contact with one 5a of the two active elements 5a, 5b and the one outer contact element 6 is in contact with the other 5b of the two active elements 5a, 5b. In each case this applies over the entire inner or entire outer circumference of the respective active element 5a, 5b.

An electro-optical modulator according to the invention can be used in particular for optical signal coding.

Since the light signal is not absorbed but modulated, coupling devices 17 are provided here at both ends of the waveguide 4 respectively. In operation, one of the coupling devices is used for coupling in and the other for coupling out an optical signal.

An electro-optical device 1 according to the invention can also be designed as a component of an interferometer, for example a Mach-Zehnder interferometer, for example a Mach-Zehnder interferometer serving as a phase modulator. This is particularly the case if the electro-optical device 1 is a modulator. Associated embodiments can be taken from FIGS. 11 and 12. FIG. 10 shows—again in analogy to FIGS. 1 and 6 with detectors and modulators known from the prior art—a Mach-Zehnder interferometer serving as a phase modulator with an electro-optical modulator known from the prior art (cf. FIG. 6).

As can be seen, the interferometer of FIG. 11 comprises a modulator 1 according to the invention of the configuration shown in FIG. 8 and the one in FIG. 12 comprises a modulator according to the invention of the configuration shown in FIG. 9. Both the interferometer of FIG. 10 and the interferometers of FIGS. 11 and 12 comprise, in addition to the modulators 1 of FIGS. 6, 8 and 9, respectively, a waveguide bypass section 19, which “bridges”, so to speak, the respective modulator and thus its interaction region 2 (FIGS. 10 and 12) or interaction regions 2 (FIG. 11), so that light originating in particular from the same source can be guided past the interaction region 2 or the two interaction regions 2 through the waveguide bypass section 19. As can be seen, the waveguide 4 is not an annularly closed waveguide, but has two open ends at which optical signals can be coupled in and out, specifically by means of the coupling devices 17.

In a manner known per se, the respective waveguide bypass section 19 forms one of two interferometer arms and the upper arm, in which the respective modulator is located, forms the second. The two interferometer arms have, as it is sufficiently known from the prior art, expediently different path lengths.

At the bifurcation points, from which the interferometer arms depart and rejoin, there is in each case a splitter 16, which can be designed, for example, as an MMI (multimode interferometer) or directional coupler or can comprise at least one such coupler. In particular, it can be a reciprocal MMI or a reciprocal directional coupler. This means that light coming from the side with one arm is divided in half between the two waveguide connections located on the opposite side of the MMI or directional coupler and vice versa, i.e. light coming from the side with two arms combined on the side with one connection.

At the input of the interferometer, optical signals are split and guided, for example, in two arms. Via an active component or several active components, shown in FIGS. 11 and 12 for one active component for example, a phase shift of the light propagating in both arms is generated. Active components can be located in all arms of an interferometer. At the output of the interferometer, the optical paths are merged and the light is superimposed. Constructive or destructive interference results from the phase position.

It should be noted that, as an alternative to coupling in and coupling out the optical signal from two opposite sides, as shown in FIGS. 8, 9, 11 and 12, the arrangement can in principle also be as shown in FIG. 13. Then the coupling in and coupling out can take place from the same side, which can be advantageous with regard to the coupling of optical fibers, which can be pre-assembled into groups in fiber blocks. For example, the waveguide 4 can be at least substantially U-shaped over all. In the high least simplified, purely schematic FIG. 13, this is shown as an embodiment of an electro-optical device 1 according to the invention, of which only one inner and two outer contact elements 6 are shown. As can be seen, the coupling devices 17 arranged at the two ends of the waveguide 4 are here adjacent to each other. Even though two separate outer contact elements 6 are shown here as an example, which corresponds to FIGS. 8 and 11, it is understood that the coupling in and coupling out from the same side, for example with the waveguide course shown in FIG. 13, can also be selected for the case of a U-shaped outer contact element 6, as can be seen in FIGS. 9 and 12.

The inventive G-S-G contact configuration of all above-described embodiments according to the invention offers the great advantage that high-frequency signals can be transmitted more interference-free to coplanar or coaxial arrangements.

For example, at least one connection device 20 can be provided for connection to a coaxial and/or coplanar conductor, as shown schematically in FIG. 14 in top view and in FIG. 15 in sectional view. The connection device 20 itself comprises three connection contact elements 21, specifically an inner connection contact element 21 serving as a ground contact and two outer connection contact elements 21, which are arranged on two sides of the inner contact element, thus practically enclosing it, and serve as signal contacts. This is therefore a G-S-G contact arrangement. It also has connection means, not further shown in the figure, for connecting a coaxial cable and/or a coplanar conductor.

The electrically conductive connection of an electro-optical device 1 according to the invention to a connection device 20 for connection to a coaxial and/or coplanar conductor can be realized, for example, by means of wires 22, as shown in FIG. 14. For this purpose, one free end of the respective wire 22 is in contact with one of the contact elements 6 of the electro-optical device 1 according to the invention and its other free end is in contact with one of the connection contact elements 21 of the connection device 20. The wires may in particular be made of metal, for example aluminium or gold.

As can be seen, the connection contact elements 21 of the connection device 20 diverge with their ends pointing upwards in the figure, which can serve to the generally larger dimensions of conventional coaxial cables or coplanar conductors.

Alternatively or in addition to a connection by means of wires 22, a bonding is also possible, as shown schematically in FIG. 15. In this case, a respective connection contact element 21 of the connection device 20 is arranged above a contact element 6 of a device 1 according to the invention or—as far as the embodiments from FIGS. 5, 9 and 12 with the continuous U-shaped outer contact element 6 are concerned—above one of the arms of the outer contact element 6. The electrically conductive connection is realized here via a bonding coat 23, via which the contact elements 6, 21 are bonded to each other. The bonding coat can consist of conductive adhesive, for example silver or gold.

It should be noted that the arrangement shown in FIGS. 14 and 15 with an electro-optical device 1 according to the invention and a connection device 20 for connection to a coplanar or coaxial conductor is an embodiment of an electro-optical arrangement according to the invention.

1. Electro-optical device (1), in particular a photodetector or a modulator, having two interaction regions (2), which each comprise a longitudinal waveguide section (3) and one or two active elements (5), the active element or elements (5) each comprising or consisting of at least one electro-optically active material, in particular graphene, the longitudinal waveguide sections (3) of the two interaction regions (2) being arranged spaced apart from one another and the active element or the respective active element (5) extending at least in sections above and/or below and/or within the longitudinal waveguide section (3) of the respective interaction region (2), and two or more contact elements (6) being provided, which contact elements (6) are each in contact with at least one of the active elements (5), wherein at least one inner contact element (6), which is arranged between the two spaced-apart longitudinal waveguide sections (3) and serves as an inner signal contact, and two outer contact elements (6), which are each arranged on the other side of the respective longitudinal waveguide section (3) with respect to the inner contact element (6) and each serve as an outer ground contact, or one outer contact element (6), which is formed at least in sections at least substantially in a U-shape with two arms (6a) spaced apart from one another and a connecting section (6b) connecting the two arms (6a) and which engages around the outside of the two longitudinal waveguide sections (3), the two arms (6a) of the outer contact element (6) each serving at least in sections as an outer ground contact, are provided.

2. Device (1) according to claim 1, wherein an inner contact element (6) is provided, which inner contact element (6) is in contact both with the active element or one of the active elements (5) of one interaction region (2) and with the active element or one of the active elements (5) of the other interaction region (2),
or wherein two inner contact elements (6) are provided, and one of the inner contact elements (6) is in contact with the active element or one active element (5) of one interaction region (2) and the other inner contact element (6) is in contact with the active element or one active element (5) of the other interaction region (2), and/or
wherein an outer contact element (6) is provided, which is in contact both with the active element or one of the active elements (5) of one interaction region (2) and with the active element or one of the active elements (5) of the other interaction region (2),
or wherein two outer contact elements (2) are provided, and one of the outer contact elements (6) is in contact with the active element or one active element (5) of one interaction region (2) and the other outer contact element (6) is in contact with the active element or one active element (5) of the other interaction region (2).

3. Device (1) according to claim 1, wherein the two longitudinal waveguide sections (3) are part of one waveguide (4).

4. Device (1) according to claim 3, wherein the waveguide (4) comprises a bifurcation with two branching arms (4c, 4d), and one of the longitudinal waveguide sections (3) is located in the region of one arm (4c, 4d) of the bifurcation respectively, preferably, wherein a splitter (16) is provided, by means of which an incoming light signal can be distributed to the two arms (4c, 4d) of the bifurcation, preferably in equal proportions.

5. Device (1) according to claim 3, wherein the waveguide (4) is characterized at least in sections by an at least substantially U-shaped course with two arms (4a) being spaced apart from one another, preferably extending at least substantially parallel to one another and in particular being rectilinear, and a preferably rectilinear connecting section (4b) connecting the two arms (4a), wherein one of the two longitudinal waveguide sections (3) lies in the region of one of the two arms (4a) respectively.

6. Electro-optical device (1), in particular a photodetector or a modulator, having an interaction region (2), which interaction region (2) has an at least substantially U-shaped longitudinal waveguide section (3), which longitudinal waveguide section (3) has two arms (4a) spaced apart from one another and a connecting section (4b) connecting the two arms (4a), and one or two at least sectionally at least substantially U-shaped active elements (5) having two arms (5a) spaced apart from one another and a connecting section (5b) connecting the two arms (5a), wherein the active element or the respective active element (5) comprises or consists of at least one electro-optically active material, in particular graphene, wherein the active element or the respective active element (5) extends at least in sections above and/or below and/or within the longitudinal waveguide section (3), and wherein two or more contact elements (6) are provided, which are each in contact with the active element or one of the active elements (5), wherein at least one inner contact element (6), which is arranged within the at least sectionally at least substantially U-shaped longitudinal waveguide section (3) and serves as an inner signal contact, and two outer contact elements (6), which are each arranged on the other side of the respective arm (4a) of the longitudinal waveguide section (3) with respect to the inner contact element (6) and each serve as an outer ground contact, or one outer contact element (6), which is formed at least in sections at least substantially U-shaped and has two arms (6a) spaced apart from one another and a connecting section (6b) connecting the two arms (6a) and which encompasses the outside of the longitudinal waveguide section (3), the two arms (6a) of the outer contact element (6) each serving at least in sections as an outer ground contact, are provided.

7. Device (1) according to claim 6, wherein the longitudinal waveguide section (3) is part of a non-annularly closed waveguide (6).

8. Device (1) according to claim 5, wherein the cross-sectional area in the region of one arm (4a) of the waveguide (4) is larger than the cross-sectional area in the region of the other arm (4a) of the waveguide (4), preferably, the cross-sectional area being larger in the first arm (4a) as viewed in the light propagation direction.

9. Device (1) according to claim 6, wherein an inner contact element (6) is provided, which is in contact both with the one arm (5a) of the active element or of one of the active elements (5) and with the other arm (5a) of the active element or of one of the active elements (5),
or two inner contact elements (6) are provided, and one of the inner contact elements (6) is in contact with the one arm (5a) of the active element or of one of the active elements (5) and the other inner contact element (6) is in contact with the other arm (5a) of the active element or of one of the active elements (5), and/or
wherein an outer contact element (6) is provided, which is in contact both with the one arm (5a) of the active element or of one of the active elements (5) and with the other arm (5a) of the active element or of one of the active elements (5),
or two outer contact elements (6) are provided, and one of the outer contact elements (6) is in contact with the one arm (5a) of the active element or of one of the active elements (5) and the other outer contact element (6) is in contact with the other arm (5a) of the active element or of one of the active elements (5).

10. Device (1) according to claim 1, wherein the device is formed as a photodetector and the interaction region or the respective interaction region (2) comprises exactly one active element (5), preferably, wherein the inner contact element or one of the inner contact elements (6) and the outer contact element or one of the outer contact elements (6) are in contact with the one active element (5), particularly preferably on opposite sides of the one active element (5).

11. Device (1) according to claim 1, wherein the device is formed as a modulator, in particular as an electro-optical modulator, and the interaction region or the respective interaction region (2) comprises two active elements (5), preferably, wherein the inner contact element or one of the inner contact elements (6) is in contact with the active element (5) of the interaction region or of the respective interaction region (2) and the outer contact element or one of the outer contact elements (6) is in contact with the other active element (5) of the interaction region or of the respective interaction region (2), or
the interaction region or the respective interaction region (2) comprises an active element (5) and an electrode, preferably, wherein the inner contact element or one of the inner contact elements (6) is in contact with the active element (5) of the interaction region or of the respective interaction region (2) and the outer contact element or one of the outer contact elements (6) is in contact with the electrode of the interaction region or of the respective interaction region (2) or vice versa.

12. Device (1) according to claim 11, wherein the two active elements (5) or the active element (5) and the electrode of the interaction region or of the respective interaction region (2) are spaced apart from one another and are arranged offset with respect to one another in such a way that they lie one above the other in sections in an overlap region.

13. Device (1) according to claim 1, wherein a waveguide bypass section (19) is provided, the waveguide bypass section (19) bridging the one interaction region (2) or the two interaction regions (2), so that light originating in particular from the same source can be guided past the one interaction region (2) or the two interaction regions (2) through the waveguide bypass section (19), preferably, wherein the device (1) is formed as an interferometer or as a component of an interferometer and/or a splitter (16) is provided by means of which light can be split on the one hand to the waveguide bypass section (19) and on the other hand to the longitudinal waveguide section (3) of the interaction region (2) or to the longitudinal waveguide sections (3) of the interaction regions (2).

14. Device (1) according to claim 1, wherein the longitudinal waveguide section (3) of the interaction region (2) or the longitudinal waveguide sections (3) of the interaction regions (2) is or are part of a waveguide (4), at one end of which a coupling device (17) for coupling light in and/or out is provided or at both ends of which a coupling device (17) for coupling light in and/or out is provided respectively.

15. Device (1) according to claim 1, wherein the at least one electro-optically active material is a material which absorbs electromagnetic radiation of at least one wavelength and generates an electrical photosignal as a result of the absorption, and/or whose refractive index changes as a function of a voltage and/or the presence of charge and/or an electric field, in particular, wherein the at least one electro-optically active material is graphene and/or at least one dichalcogenide, in particular two-dimensional transition dichalcogenide, and/or heterostructures of two-dimensional materials and/or germanium and/or lithium niobate and/or at least one electro-optical polymer and/or silicon and/or at least one compound semiconductor, in particular at least one III-V semiconductor and/or at least one II-VI semiconductor.

16. Electro-optical arrangement, comprising at least one electro-optical device (1) according to claim 1, and a connection device (20) for connecting to a coaxial and/or coplanar conductor, wherein the connection device (20) comprises one or more inner connection contact elements (21) serving as a ground contact and one or more outer connection contact elements (21) serving as a signal contact, and wherein the inner contact element(s) (6) of the electro-optical device (1) is/are or can be connected to the inner connection contact element(s) (21) of the connection device (20), and wherein the outer contact element(s) (6) of the electro-optical device (1) is/are or can be connected to the outer connection contact element(s) (21) of the connection device (20).

17. Semiconductor apparatus comprising a chip and at least one, preferably a plurality of electro-optical devices (1) according to claim 1, wherein the device (1) or the devices (1) are preferably arranged on the chip or on a coat arranged above the chip.

18. Semiconductor apparatus according to claim 17, wherein the device or the respective device (1) is part of a photonic platform fabricated on the chip or bonded to the chip.

19. Semiconductor device comprising a wafer (8) and at least one, preferably a plurality of devices (1) according to claim 1, wherein the device (1) or the devices (1) are preferably arranged on the wafer (8) or on a coat arranged above the wafer (8).

20. Semiconductor device according to claim 19, wherein the device or the respective device (1) is part of a photonic platform fabricated on the wafer (8) or bonded to the wafer (8).

21. Use of an electro-optical device (1) according to claim 1 in such a way that the inner contact element or the inner contact elements (6) of the electro-optical device (1) is/are connected to the ground contact(s) of a coaxial or coplanar conductor or of a connection device (20) for connecting to a coaxial or coplanar conductor, and that the outer contact element or the outer contact elements (6) of the electro-optical device (1) is/are connected to the signal contact(s) of a coaxial or coplanar conductor or of a connection device (20) for connecting to a coaxial or coplanar conductor.
